(19) United States
(12) Patent Application Publication
(10) Pub. No.: US 2015/0187832 A1
(43) Pub. Date: Jul. 2, 2015

(54) IMAGE SENSOR AND METHOD FOR FABRICATING THE SAME

(71) Applicant: UNITED MICROELECTRONICS CORP., Hsin-Chu City (TW)

(72) Inventor: Cheng-Hung Yu, Taoyuan County (TW)

(73) Assignee: UNITED MICROELECTRONICS CORP., Hsin-Chu City (TW)

(21) Appl. No.: 14/140,571

(22) Filed: Dec. 26, 2013

(51) Int. Cl. H01L 27/146

(52) U.S. Cl. CPC H01L 27/14685; H01L 27/14621

(57) ABSTRACT

A method for fabricating image sensor is disclosed. The method includes the steps of: providing a substrate having a dielectric layer thereon; forming a plurality of filtering layers on the dielectric layer; patterning the filtering layers for forming a first pass filter; coating a material layer on the dielectric layer such that a top surface of the material layer is even with a top surface of the first pass filter; and forming a plurality of color filters on the first pass filter.

### BACKGROUND OF THE INVENTION

1. Field of the Invention

The invention relates to an image sensor and fabrication method thereof.

2. Description of the Prior Art

As the development of electronic products progresses, the demand for related components has increased as well. For example, as the development of digital cameras and scanners progresses, the demand for image sensor increases accordingly. In general, today's image sensors in common usage are divided into two main categories: charge coupled device (CCD) sensors and CMOS image sensors (CIS). The application of CMOS image sensors has increased significantly for several reasons. Primarily, CMOS image sensors have certain advantages of offering low operating voltage, low power consumption, and the ability for random access. Additionally, CMOS image sensors are currently capable of integration with the semiconductor fabrication process.

The CMOS image sensor separates (i.e., classifies) incident light into a combination of light of different wavelengths. The light of different wavelengths is received by respective sensing elements and is subsequently transferred into digital signals of different intensities. For example, the CMOS image sensor can consider incident light as a combination of red, blue, and green light. Those wavelengths are subsequently received by photodiodes, and then transformed into digital signals. However, in order to separate incident light, a monochromatic color filter array (CFA) must be set above every optical sensor element.

However, conventional color filters made of organic or organometallic materials are facing issues like degradation because of light exposure and relative low heat resistances. For instance, organic color filters used at the moment cannot support a temperature over 300° C., which ultimately affects the performance of the device substantially.

### SUMMARY OF THE INVENTION

It is therefore an objective of the present invention to provide a method for fabricating image sensors to resolve the aforementioned drawbacks.

According to a preferred embodiment of the present invention, a method for fabricating image sensor is disclosed. The method includes the steps of: providing a substrate having a dielectric layer thereon; forming a plurality of filtering layers on the dielectric layer; patterning the filtering layers for forming a first pass filter; coating a material layer on the dielectric layer such that a top surface of the material layer is even with a top surface of the first pass filter; and forming a plurality of color filters on the first pass filter.

According to another aspect of the present invention, a method for fabricating image sensor is disclosed. The method includes the steps of: providing a substrate having a dielectric layer thereon; forming a trench in the dielectric layer; forming a plurality of color filters in the trench; covering a plane layer on the dielectric layer and the color filters; and forming a pass filter on the plane layer.

According to another aspect of the present invention, an image sensor is disclosed. The image sensor includes: a substrate having a dielectric layer thereon; a material layer on the dielectric layer; a first pass filter embedded in the material layer, wherein a top surface of the first pass filter is even with a top surface of the material layer; and a plurality of color filters on the first pass filter.

According to another aspect of the present invention, an image sensor is disclosed. The image sensor includes: a substrate having a dielectric layer thereon; a plurality of color filters embedded in the dielectric layer; a plane layer on the color filters and the dielectric layer; and a pass filter on the plane layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-2 illustrate a method for fabricating an image sensor according to a first embodiment of the present invention.

FIG. 3 illustrates a method for fabricating an image sensor according to a second embodiment of the present invention.

FIGS. 4-6 illustrates a method for fabricating an image sensor according to a third embodiment of the present invention.

### DETAILED DESCRIPTION

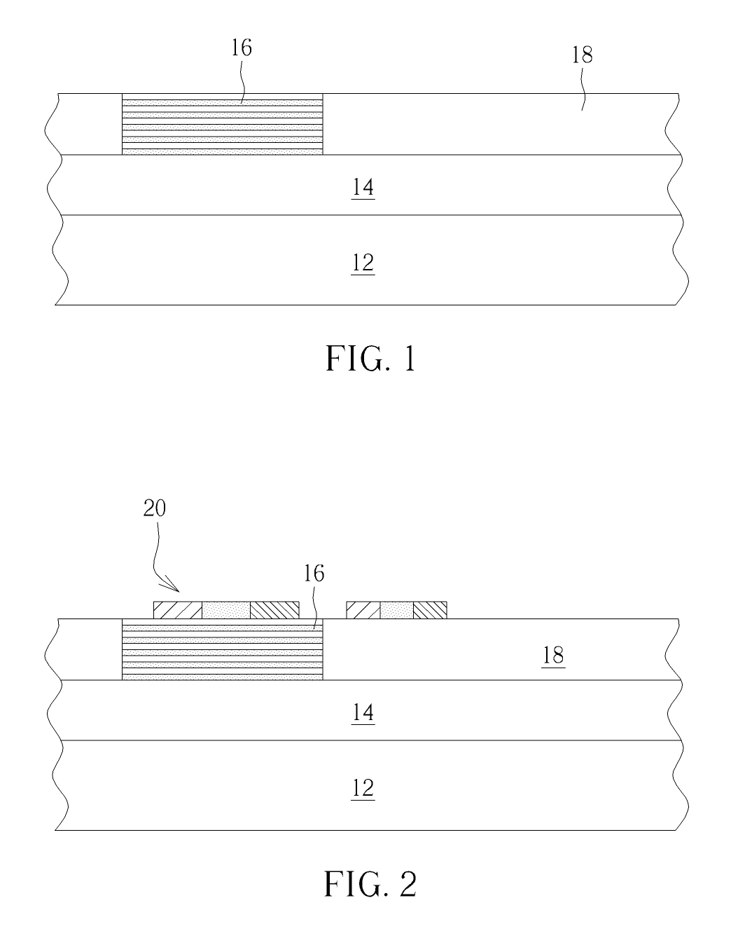

Referring to FIGS. 1-2, FIGS. 1-2 illustrate a method for fabricating an image sensor according to a first embodiment of the present invention. As shown in FIG. 1, a substrate 12 having a plurality of optical elements (not shown) arranged according to a matrix and a plurality of metal interconnects (not shown) are provided. A dielectric layer 14 is then formed on the substrate 12 thereafter.

Next, a plurality of inorganic films of high refractive index and a plurality of inorganic films (not shown) of low refractive index are formed interchangeably one layer over another on the dielectric layer 14 . This forms a plurality of filtering layers on the dielectric layer 14, in which the filtering layers comprise inorganic materials selected from a group consisting of SiN and SiO₂, TiO₂ and SiO₂, Ta₂O₅ and SiO₂, or Ag and SiO₂. Preferably, the refractivity of each filtering layer is determined by the material being used, such that the filtering layers are stacked one layer over another, preferably with odd number layers consisting of a material different from even number layers.

For instance, a plurality of odd number filtering layers consisting of TiO₂ may be stacked alternately on top of a plurality of even number layers layer consisting of SiO₂, or a plurality of odd number filtering layers consisting of Ta₂O₅ may be stacked alternately on top of a plurality of even number layers consisting of SiO₂ to provide filtering layers of high refractive index and low refractive index.

Next, a patterning transfer process is performed by dry etching and lift off process to pattern the filtering layers into a pass filter 16. The pass filter 16 is preferably an IR cut filter utilizing for filtering infrared lights, but not limited thereto.

After the pass filter 16 with high refractive index and low refractive index is formed, a material layer 18 is coated on the dielectric layer 14 and the pass filter 16, and an exposure process is performed by adjusting the energy of the exposure and/or adjusting the depth of focus (DOF) so that the top surface of the material layer 18 is even with the top surface of the pass filter 16. According to a preferred embodiment of the present invention, the material layer 18 is consisting of a negative photoresist, but not limited thereto.

Next, as shown in FIG. 2, a plurality of color filters 20 are formed on the pass filter 16 and the material layer 18. The color filters 20 may be selected from a group consisting of red color filter, blue color filter, green color filter, cyan color filter, magenta color filter, and yellow color filter, which are all within the scope of the present invention. As the fabrication of color filters is well known to those skilled in the art, the details of which are not explained herein for the sake of brevity.

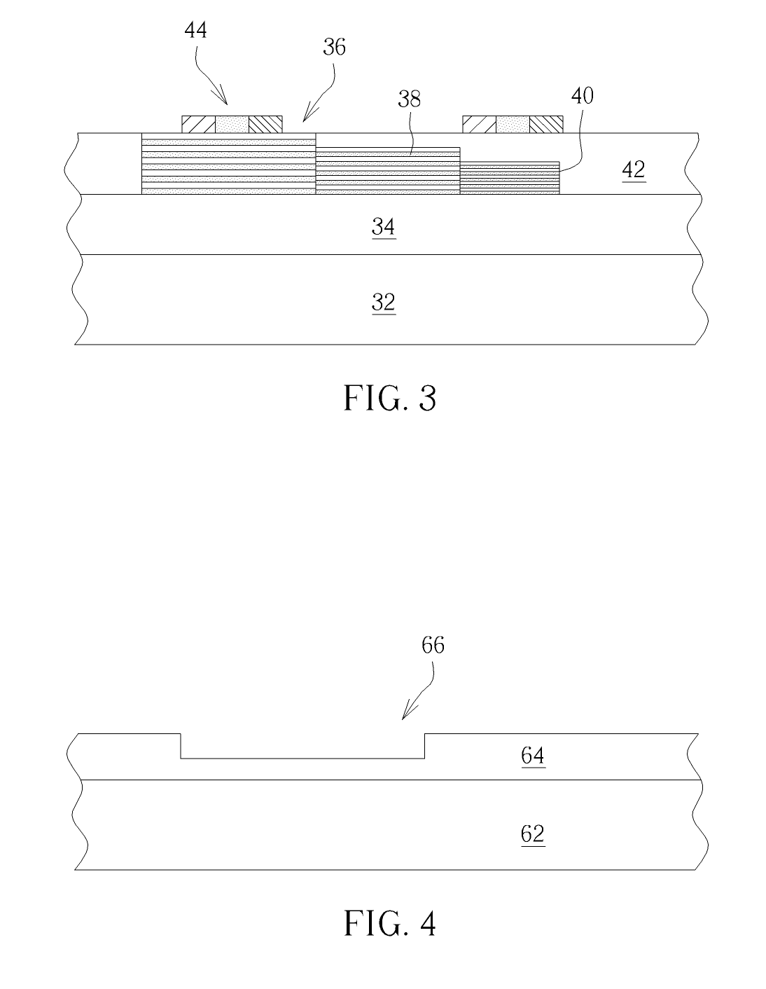

Referring to FIG. 3, FIG. 3 illustrates a method for fabricating an image sensor according to a second embodiment of the present invention. As shown in FIG. 3, a substrate 32 having a plurality of optical elements (not shown) arranged according to a matrix and a plurality of metal interconnects (not shown) are provided. A dielectric layer 34 is then formed on the substrate 32 thereafter.

Next, similar to the aforementioned embodiment, a plurality of inorganic films of high refractive index and a plurality of inorganic films of low refractive index are formed interchangeably one layer over another on the dielectric layer 34. This forms a plurality of filtering layers (not shown) on the dielectric layer 34, in which the filtering layers comprise SiN and SiO₂, TiO₂ and SiO₂, Ta₂O₅ and SiO₂, or Ag and SiO₂. Preferably, the refractivity of each filtering layer is determined by the material being used, such that the filtering layers are stacked one layer over another, preferably with odd number layers consisting of a material different from even number layers.

For instance, a plurality of odd number filtering layers consisting of TiO₂ may be stacked alternately on top of a plurality of even number layers layer consisting of SiO₂, or a plurality of odd number filtering layers consisting of Ta₂O₅ may be stacked alternately on top of a plurality of even number layers consisting of SiO₂ to provide filtering layers with high refractive index and low refractive index.

Next, a patterning transfer process is performed by dry etching and lift off process to pattern the filtering layers into a first pass filter 36.

After the first pass filter 36 is formed, additional pass filters could be formed adjacent to the first pass filter 36, such as a second pass filter 38 and a third pass filter 40. Depending on the material being used, the three pass filters 36, 38, 40 depicted in FIG. 3 preferably have different heights. The pass filters 36, 38, 40 are preferably IR cut filters, but could also be filters of other types, which are all within the scope of the present invention.

After the pass filters 36, 38, 40 are formed, a material layer 42 is coated on the dielectric layer 34 and the pass filters 36, 38, 40, and an exposure process is performed by adjusting the energy of the exposure and/or adjusting the depth of focus (DOF) so that the top surface of the material layer 42 is even with the top surface of the first pass filter 36. As the second pass filter 38 and the third pass filter 40 have relatively lower heights, the material layer 42 preferably covers not only on the dielectric layer 34 but also the second pass filter 38 and the third pass filter 40. The material layer 42 is preferably consisting of a negative photoresist, but not limited thereto.

Next, in this embodiment, a plurality of color filters 44 are formed on the first pass filter 36 and the material layer 42, but could also be formed on the second pass filter 38 and the third pass filter 40 depending on the demand of the product, which is also within the scope of the present invention. The color filters 44 may be selected from a group consisting of red color filter, blue color filter, green color filter, cyan color filter, magenta color filter, and yellow color filter, which are all within the scope of the present invention. As the fabrication of color filters is well known to those skilled in the art, the details of which are not explained herein for the sake of brevity.

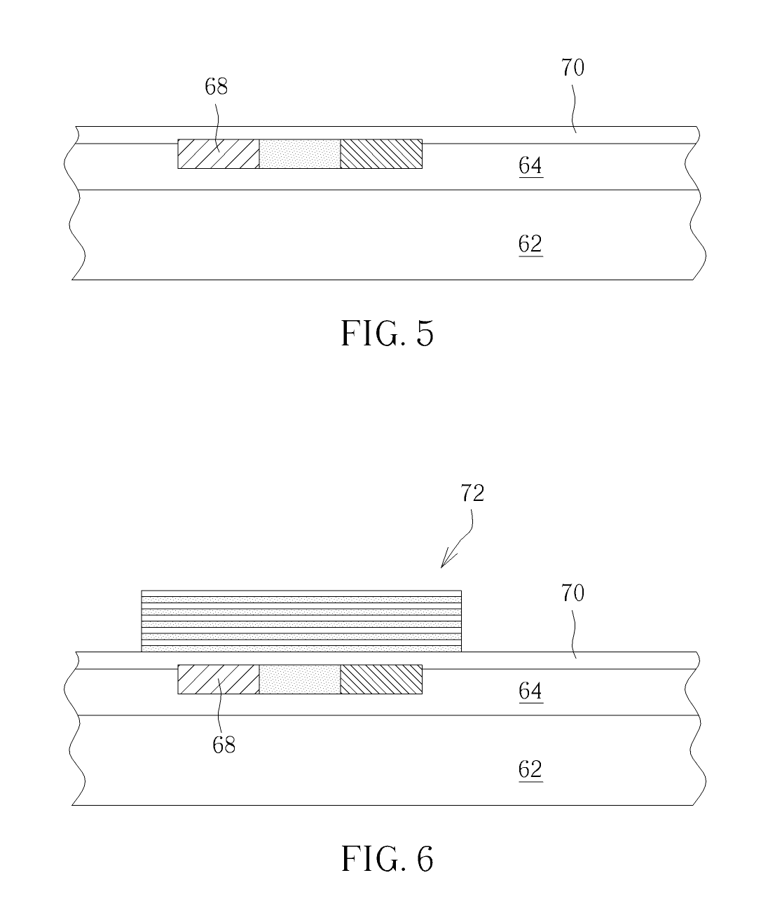

Referring to FIGS. 4-6, FIGS. 4-6 illustrate a method for fabricating an image sensor according to a third embodiment of the present invention. As shown in FIG. 4, a substrate 62 having a plurality of optical elements (not shown) arranged according to a matrix and a plurality of metal interconnects (not shown) are provided. A dielectric layer 64 is then formed on the substrate thereafter.

Next, a pattern transfer process is performed to form at least a trench 66 in the dielectric layer 64. For instance, a patterned photoresist (not shown) may be disposed on a surface of the dielectric layer 64, and an etching process is performed by utilizing the patterned photoresist as a mask to remove a portion of the dielectric layer 64 not covered by the patterned photoresist for forming at least a trench 66 in the dielectric layer 64.

After stripping the patterned photoresist, as shown in FIG. 5, a plurality of color filters 68 are formed in the trench 66. The color filters 68 can be selected from a group consisting of red color filter, blue color filter, green color filter, cyan color filter, magenta color filter, and yellow color filter, but not limited thereto. Next, a plane layer 70 is covered on the dielectric layer 64 and the color filters 68 to provide a plane surface. Preferably, the thickness of the plane layer 70 is from 1000 Angstroms to several thousand Angstroms, and the plane layer 70 is consisting of low stress silicon oxide, but not limited thereto.

As shown in FIG. 6, a pass filter 72 is then formed on the color filters 68 and the plane layer 70. It should be noted that as the color filters typically cannot support temperatures greater than 300° C. , the formation of the pass filter 72 is preferably accomplished by a low temperature deposition process with temperatures less than 300° C., such as a physical vapor deposition-electron beam gun evaporation (PVD-EBGE) or chemical vapor deposition (CVD) process.

Similar to the aforementioned embodiments, the formation of the pass filter 72 may be accomplished by first forming a plurality of filtering layers on the plane layer 70, in which the filtering layers comprise SiN and SiO₂, TiO₂ and SiO₂, Ta₂O₅ and SiO₂, or Ag and SiO₂. Preferably, the refractivity of each filtering layer is determined by the material being used, such that the filtering layers are stacked one layer over another, preferably with odd number layers consisting of a material different from even number layers.

For instance, a plurality of odd number filtering layers consisting of TiO₂ may be stacked alternately on top of a plurality of even number layers layer consisting of SiO₂, or a plurality of odd number filtering layers consisting of Ta₂O₅ may be stacked alternately on top of a plurality of even number layers consisting of SiO₂ to provide filtering layers with high refractive index and low refractive index. Next, a patterning transfer process is performed by dry etching and lift off process to pattern the filtering layers into the pass filter 72. This completes the fabrication of an image sensor according to a third embodiment of the present invention.

Overall, the present invention provides an approach of integrating pass filters and color filters by either using a material layer to create a plane surface with the pass filter before forming the color filters, or embedding color filters within a trench of the dielectric layer before forming a plane material layer and pass filter thereon. By integrating pass filters consisting of inorganic filtering layers with color filters and also employing a material layer to create a plane surface with the pass filter and the color filters, the present invention could improve the drawbacks of color filter thickness variations and coating striations found in conventional image sensor structures, and also provide image sensors with lower fabrication cost that are capable of enduring higher temperature processes.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating image sensor, comprising:
providing a substrate having a dielectric layer thereon;
forming a plurality of filtering layers on the dielectric layer;
patterning the filtering layers for forming a first pass filter;
coating a material layer on the dielectric layer such that a top surface of the material layer is even with a top surface of the first pass filter; and
forming a plurality of color filters on the first pass filter.

2. The method of claim 1, further comprising forming a plurality of inorganic films of high refractive index and a plurality of inorganic films of low refractive index interchangeably one layer over another for forming the filtering layers.

3. The method of claim 1, wherein the filtering layers comprise SiN and SiO₂, TiO₂ and SiO₂, Ta₂O₅ and SiO₂, or Ag and SiO₂.

4. The method of claim 1, further comprising:
coating the material layer on the dielectric layer and the first pass filter; and
performing an exposure process such that the top surface of the material layer is even with the top surface of the first pass filter.

5. The method of claim 1, wherein the material layer comprises a negative photoresist.

6. The method of claim 1, further comprising forming a second pass filter on the dielectric layer before coating the material layer, wherein the height of the second pass filter is different from the first pass filter.

7. A method for fabricating image sensor, comprising:
providing a substrate having a dielectric layer thereon;
forming a trench in the dielectric layer;
forming a plurality of color filters in the trench;
covering a plane layer on the dielectric layer and the color filters; and
forming a pass filter on the plane layer.

8. The method of claim 7, wherein the plane layer comprises silicon oxide.

9. The method of claim 7, further comprising:
forming a plurality of filtering layers on the plane layer; and
patterning the filtering layers for forming the pass filter.

10. The method of claim 9, further comprising forming a plurality of inorganic films with high refractive index and a plurality of inorganic films with low refractive index interchangeably one layer over another for forming the filtering layers.

11. An image sensor, comprising:
a substrate having a dielectric layer thereon;
a material layer on the dielectric layer;
a first pass filter embedded in the material layer, wherein a top surface of the first pass filter is even with a top surface of the material layer; and
a plurality of color filters on the first pass filter.

12. The image sensor of claim 11, wherein the first pass filter comprise a plurality of inorganic films with high refractive index and low refractive index stacked interchangeably one layer over another.

13. The image sensor of claim 11, wherein the first pass filter comprise SiN and SiO₂, TiO₂ and SiO₂, Ta₂O₅ and SiO₂, or Ag and SiO₂.

14. The image sensor of claim 11, wherein the material layer comprises a negative photoresist.

15. The image sensor of claim 11, further comprising a second pass filter on the dielectric layer, wherein the height of the second pass filter is different from the first pass filter.

16. An image sensor, comprising:
a substrate having a dielectric layer thereon;
a plurality of color filters embedded in the dielectric layer;
a plane layer on the color filters and the dielectric layer; and
a pass filter on the plane layer.

17. The image sensor of claim 16, wherein the plane layer comprises silicon oxide.

18. The image sensor of claim 16, wherein the pass filter comprise a plurality of inorganic films with high refractive index and low refractive index stacked interchangeably one layer over another.

19. The image sensor of claim 16, wherein the pass filter comprise SiN and SiO₂, TiO₂ and SiO₂, Ta₂O₅ and SiO₂, or Ag and SiO₂.
